(19) United States
(12) Patent Application Publication
(10) Pub. No.: US 2019/0230305 A1
(43) Pub. Date: Jul. 25, 2019

(54) IMAGE SENSOR

(71) Applicant: TELEDYNE E2V (UK) LIMITED, Essex (GB)

(72) Inventors: Paul Andrew Jerram, Essex (GB); Konstantin Stefanov, Cambridgeshire (GB)

(73) Assignee: TELEDYNE E2V (UK) LIMITED, Essex (GB)

(21) Appl. No.: 16/093,568

(22) PCT Filed: Apr. 13, 2017
(86) PCT No.: PCT/EP2017/059024

§ 371 Date: Oct. 12, 2018

(30) Foreign Application Priority Data
Apr. 15, 2016 (GB) 1606626.8

(51) Int. Cl. H04N 5/372; H01L 27/148; H04N 5/3725

(52) U.S. Cl. CPC H04N 5/37213; H04N 5/3725; H01L 27/14806

(57) ABSTRACT

A CCD image sensor of the type for providing charge multiplication by impact ionisation has an image area and a plurality of pixels. A separate multiplication register has a plurality of multiplication elements arranged to receive charge from the pixels of the image area. Each multiplication element comprises a sequence of electrodes operable to cause multiplication, the electrodes of each multiplication element being adjacent one another and non-overlapping. The non-overlapping arrangement may be manufactured by a CMOS process thereby providing a CCD image sensor with the advantages of CCD multiplication but using a CMOS manufacturing process.

### FIELD OF THE INVENTION

This invention relates to image sensors, particularly semiconductor image sensors.

### BACKGROUND

In a typical CCD image sensor, signal charge representative of incident radiation is accumulated in an array of pixels in an image area. Following an integration period, signal charge is transferred to a store section and then to an output register by applying appropriate clocking or drive pulses to control electrodes. If the illumination is pulsed or shuttered, transfer directly from image to register can occur during the non-illuminated period without the use of a store section. The signal charge is then read out from the output register and applied to a charge detection circuit to produce a voltage that is representative of the amount of signal charge. The sensitivity of such a device is limited by the noise of the charge to voltage conversion process and that introduced by the subsequent video chain electronics.

An electron multiplying CCD (EMCCD) overcomes this limitation and is disclosed in our earlier published UK patent application GB-A-2,371,403, as shown in FIG. 1. A CCD image sensor 1 comprises an image area 2, a store section 3 and an output or read-out register 4, each of these components being found in a conventional CCD imager. The output register 4 is extended serially to give a multiplication register 5, the output of which is connected to a charge detection circuit 6.

During operation of the device, incident radiation is converted at the image area 2 into signal charge which is representative of the intensity of the radiation impinging on the array of pixels making up the image array. Following the image acquisition period, drive pulses are applied to control inputs 7 to transfer the charge accumulated at the pixels of the image area 2 to the store section 3. Simultaneously with this, drive pulses are also applied to control inputs 8 at the store section 3 to cause charge to be transferred from row to row as indicated by the arrow, the last row of charge held in elements in row 3 being transferred in parallel to the output register 4.

When a row of signal charge has been transferred into the output register 4, appropriate drive pulses are applied to the inputs 9 to sequentially transfer the charge from the elements of the output register to those of the multiplication register 5. In this embodiment, the multiplication register is of similar architecture to the output register in so far as the channel doping is concerned with the addition of an electrode for multiplication.

To achieve multiplication of charge in each of the elements of the multiplication register 5, sufficiently high amplitude drive pulses are applied to control inputs 10 to both transfer signal charge from one element to the next adjacent element in the direction shown by the arrow and also to increase the level of signal charge due to impact ionisation by an amount determined by the electric field within each element as defined by the amplitude of the drive pulses and physical dimensions of each element. Thus, as each packet of charge is transferred from one element to the next through the multiplication register, the signal charge increases. The charge detected at circuit 6 is thus a multiplied version of the signal charge collected in the output register 4. The overall dynamic range, namely the ratio of signal to noise at the output, is therefore increased, with a consequent increase in the device sensitivity. At each stage of the multiplication register, the signal charge is increased. Each signal charge packet stored in the output register 4 undergoes an identical multiplication process as each travels through all the elements of the multiplication register 5.

A multiplication element of known type is shown in FIG. 2. It is noted that this is a schematic cross section and that actual physical arrangement of electrodes will be discussed later. The element comprises a base 20 of p-type silicon, an n-type layer 22 and a gate dielectric layer 24 which may, as an example, comprise a layer of Si3N4 over SiO2 or SiO2 only. On the gate dielectric layer, each element has four electrodes shown as normal clocked electrodes ϕ1 (phase 1) 26 and ϕ3 (phase 3) 28, a DC electrode ϕDC (DC gate) 30 and a high voltage electrode ϕ2HV (HV gate) 32. These are the control electrodes shown as 10 in FIG. 1. The element provides gain by the clocking voltages at the electrodes being such that a relatively high voltage at electrode ϕ2HV 32 causes impact ionisation of charge. Impact ionisation occurs when a sufficiently high electric field is generated in the channel by the voltage difference between the high voltage and DC electrodes and the dimensions (dielectric thickness and depth of channel), such that electrons moving within the field and colliding with the lattice of the silicon liberate further electrons.

Due to the similarity to an MOS transistor structure the electrodes are often referred to as gate electrodes and the underlying dielectric layer as the gate dielectric or gate oxide.

A schematic cross section of a single multiplication element is given in FIGS. 3(a) and (b). The multiplication element of the multiplication register is made up of four phases although other configurations could be possible. ϕ1 and ϕ3 are clocked as the normal read-out register phases used for section 4. ϕDC (DC gate) is a DC phase that separates ϕ1 from the HV gate ϕ2HV. The high voltage electrode ϕ2HV, the multiplication phase, is a clocked phase but using a much greater amplitude than ϕ1 and ϕ3. Initially, charge is received in the element under ϕ1 as shown in FIG. 3(a). On the high to low transition of ϕ1, the signal originally under ϕ1 will drift to ϕ2. The potential on ϕ2 is set high enough so that the fields experienced by the electron signal will cause impact ionisation to take place as shown in FIG. 3(b). Once the signal electrons and the electrons created by the impact ionisation are collected under the HV gate ϕ2HV the total amplified signal can then be transferred by switching ϕ2HV low and Ø3 high. The process is repeated through all the gain (multiplication) elements in the multiplication register. As an example, the device could have 591 gain elements. If the impact ionisation increases the signal by 1% at each element, the combined gain of the multiplication register of the CCD will be 1.01^{∧}591=358.

As shown, charge is increased in each (multiplication) element by application of voltage at ϕ2HV which causes additional electrons to form from the impact ionisation process. It is noted, for the avoidance of doubt, that the voltages shown are clocked and so vary in magnitude. The voltages are shown at a given instant. Again it is stressed that this is a schematic cross section and does not show the physical electrode arrangement. The actual physical arrangement comprises overlapping electrodes formed by multiple levels of deposition.

Various alternative attempts at electron multiplication (EM) have been proposed using CMOS technology, rather than CCD technology. In one implementation (U.S. Pat. No. 7,538,307) charge is transferred repetitively between three gates within the image area adjacent each photosensitive element and multiplied in the process. In another implementation (U.S. Pat. No. 7,755,685), EM gain is achieved by circulating the charge in a loop around the photosensitive element within the pixel area, passing through at least one EM stage per loop. In another implementation of EM gain using pinned photodiodes (PPD) elements, the gain is accomplished using a high voltage gate positioned within the main photosensitive PPD element.

### SUMMARY

We have appreciated the need to improve upon the efficiency of CCD multipliers, but without the disadvantages of the above mentioned prior art that uses EM elements within the pixel, which may have detrimental effect on the fill factor and the quantum efficiency.

The invention is defined in the independent claims to which reference is directed. Some embodiments are defined in the dependent claims.

In particular, there is provided a CCD image sensor of the type for providing charge multiplication by impact ionisation, comprising an image area having a plurality of pixels and a separate multiplication register having a plurality of multiplication elements arranged to receive charge from the pixels of the image area, each multiplication element comprising a sequence of electrodes operable to cause charge multiplication, wherein the electrodes of each multiplication element are adjacent one another and non-overlapping.

An embodiment of the invention has various advantages over conventional CCD multiplication devices. The use of adjacent non-overlapping electrodes within multiplication elements allows standard manufacturing techniques to be used, such as CMOS techniques. However, unlike conventional CMOS EM imagers, in which multiplication is provided within or adjacent image pixels, gain uniformity over the whole device is provided. This is because charge from image pixels is transferred to a separate multiplication register and so through the same multiplication elements, rather than multiplication elements within pixels which may suffer due to process non-uniformities. Preferably, the electrodes are derived from a single layer, such as by etching using a CMOS process. Such an approach allows narrow gaps to be created between electrodes so as to provide the sufficiently high fields required from relatively low voltages in comparison to existing EM CCD image sensors. An embodiment may have a plurality of multiplication registers, each multiplication register arranged to receive charge from a subset of the pixels of the image area

### BRIEF DESCRIPTION OF THE DRAWINGS

Some ways in which the invention may be performed are described in more detail by way of example with reference to the accompanying drawings, in which:

FIG. 1: is a schematic view of a known EMCCD imager having a multiplication register;

FIG. 2: is a schematic view of a cross section of a multiplication element of a multiplication register;

FIG. 3: shows voltage levels of a multiplication element;

FIG. 4: is a schematic diagram of a first arrangement embodying the invention;

FIG. 5: is a schematic diagram of a second arrangement embodying the invention;

FIG. 6: is a schematic diagram of a third arrangement embodying the invention;

FIG. 7 shows the measured electron multiplication gain of a device embodying the invention;

FIG. 8 shows the electron multiplication gain in a known device such as the e2v CCD97;

FIG. 9 shows a pixel according to an embodiment of the invention;

FIGS. 10a-c show the manufacturing steps in a known CCD process;

FIGS. 11a-b show the manufacturing steps in a CMOS process for implementing an embodiment of the invention; and

FIG. 12 shows an optical device embodying the invention.

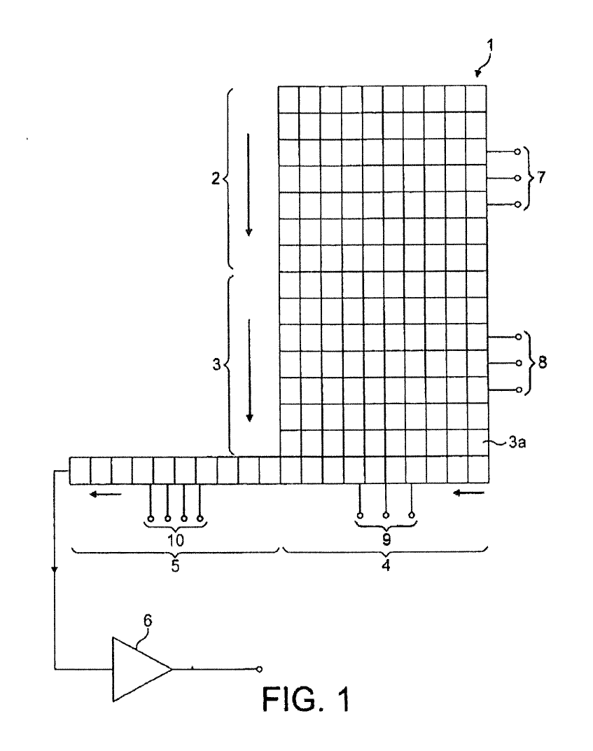

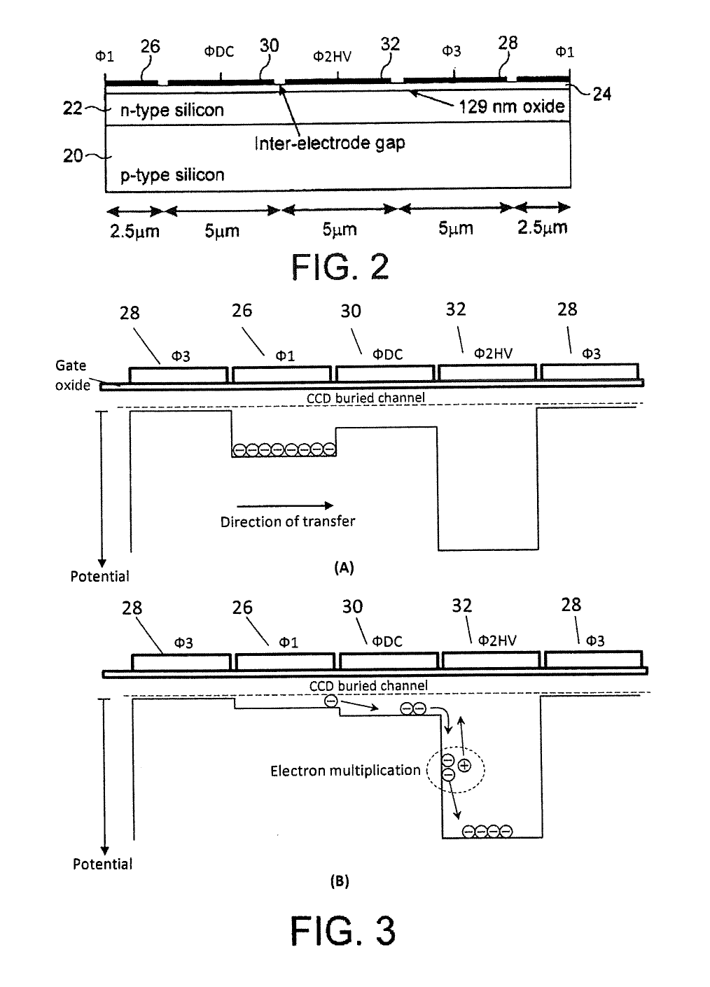

### DETAILED DESCRIPTION

An embodiment may be an image sensor, a semiconductor-based imaging device, a method of manufacturing a semiconductor-based image sensor or imager device, semiconductor image sensor modules, cameras and other optical devices including semiconductor image sensor modules.

The present disclosure describes an arrangement that significantly reduces the voltage required to achieve EM gain values compared to traditional EM CCDs. By using low voltage CMOS arrangements for EM elements the voltage level at the HV Gate can be reduced by a factor of at least 2, leading to the added advantage of a reduction of the power dissipation by a factor of at least 4.

In addition, the electron multiplication is realised outside the photosensitive area of the device, giving higher fill factor and improved quantum efficiency. This allows the photosensitive area to be optimised for only electro-optical performance and in particular for lower dark current. The electron multiplication provides a gain from input to output. Gain uniformity may also be improved in an embodiment due to the use of common gain elements per column or for the whole device. The number of EM elements is reduced in comparison with devices using EM per pixel, resulting in reduced power dissipation.

In a low voltage CMOS fabrication process, as used in an embodiment, the gate dielectric is much thinner than in traditional CCD technology; typically the CMOS gate dielectric is less than 20 nm thick while in EMCCDs it is usually more than 100 nm thick. For example, the dielectric thickness used may be 12.5 nm in a 5V CMOS process, but the dielectric breakdown voltage may be much higher than 5V. In 3.3V devices the dielectric may be 7 nm thick. In general, the thickness of dielectric in an embodiment is less than 20 nm.

In such a CMOS fabrication process normally a single polysilicon layer is used to manufacture the gates of the charge transfer structure, and the gaps between electrodes are obtained using deep-submicron etching. This process could achieve inter-electrode gaps below 100 nm. In contrast, traditional CCD technology uses multiple layers of polysilicon as gate electrodes. After each layer of polysilicon is deposited and patterned, its surface is thermally oxidised until a thin layer of silicon dioxide is grown. This oxide insulates any polysilicon layer from any subsequent polysilicon layers deposited on top of it, and forms the inter-electrode gap with the polysilicon serving as various electrodes. Usually, the inter-electrode gap created by polysilicon oxidation has thickness in the range 200 to 300 nm.

The effects of the thinner gate dielectric and narrower inter-electrode gaps combine to allow the generation of higher electric field at the same applied voltage (or generating higher electric field than possible in traditional designs), thus increasing the EM gain for the same applied voltage. Simulations indicate that the voltage applied to the HV Gate can be reduced by at least a factor of 2 while achieving the same EM gain.

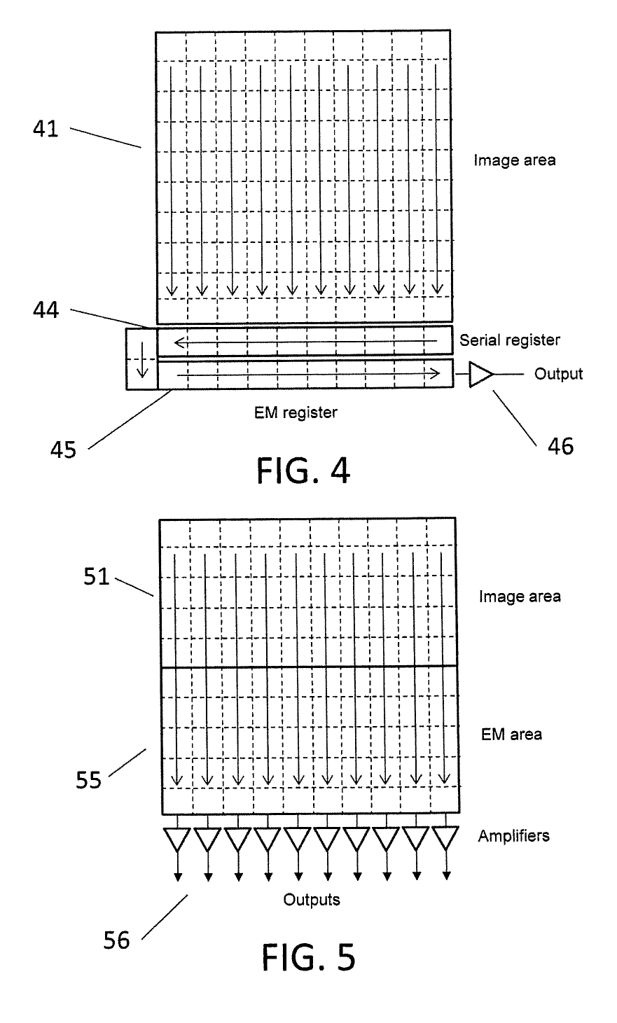

FIG. 4 shows one possible architecture for the EM device in an image sensor embodying the invention using low voltage CMOS manufacturing process. This is similar to the traditional EM CCD architecture. This example is a ‘full frame’ CCD architecture without a store section between the image and register, though a store region could be inserted in an embodiment if desired. The device is manufactured according to a CMOS process, an example of which is given later. An image area 41 comprises pixels arranged to receive illumination and to generate charge. After an illumination period, the charge in each pixel is clocked to a serial register 44 and then to a multiplication register 45. An output amplifier 46 then converts the amplified charge to an output signal.

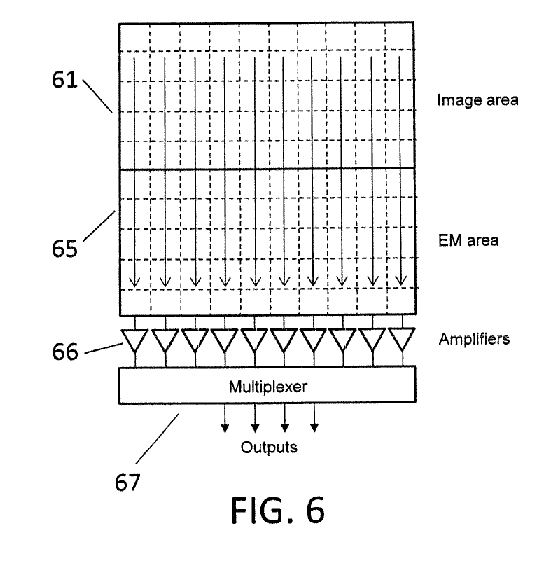

Typically CCD processes do not have capability for integrating logic and amplifiers using complementary MOS devices. FIG. 5 and FIG. 6 show two further embodying architectures using column-parallel read-out. The high density output circuitry becomes possible by the use of deep-submicron CMOS process. FIG. 5 shows an arrangement of an image sensor having similar features as before, namely an image area 51 having pixels manufactured according to a CMOS process and arranged to generate charge. The charge is clockable as previously described, after an illumination period, to a plurality of multiplication registers 55 arranged as an electron multiplying area. In this example, each column of pixels in the image area 51 has a corresponding column of multiplication elements and a corresponding output amplifier 56.

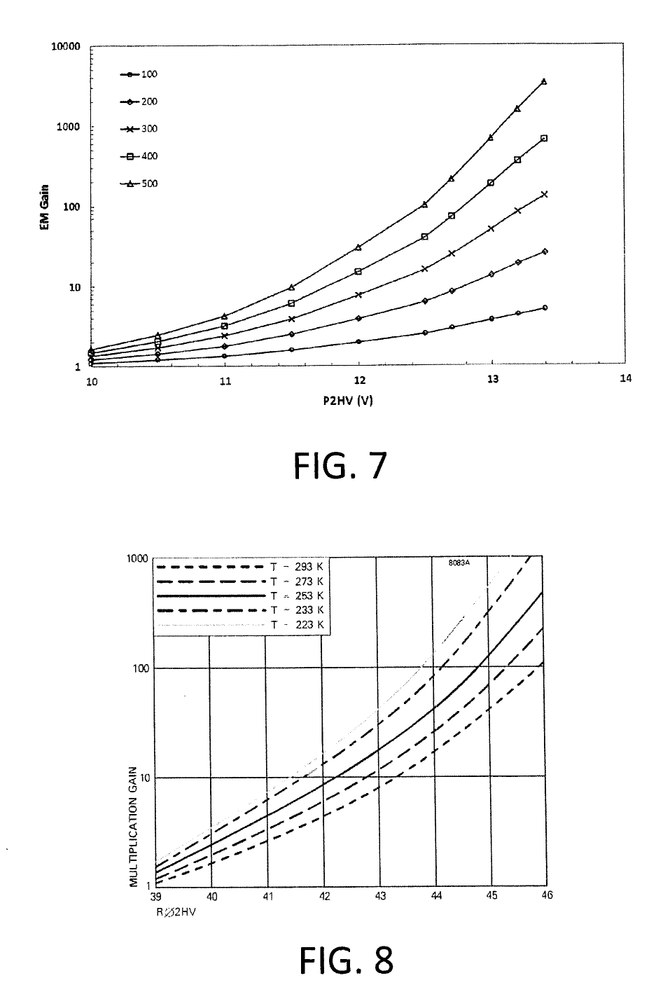

FIG. 7 shows the measured EM gain in a prototype device embodying the invention using the described low voltage CMOS manufacturing process, and for comparison FIG. 8 shows the EM gain in an e2v CCD97, a typical representative EMCCD. Due to the higher electric fields possible in the CMOS device the required high voltage clock amplitude is reduced from ≈46V to ≈13.5V for the same gain of 1000. This reduction of operating voltages could reduce the power dissipation in the EM circuitry by a factor of 10 or more, as the power is proportional to the voltage squared.

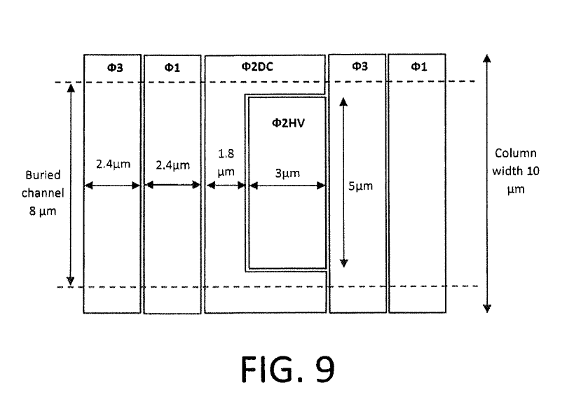

FIG. 9 shows the dimensions of one multiplication element of an embodiment with a width of 10 μm, which would be the column pitch in the devices shown in FIGS. 4 and 5.

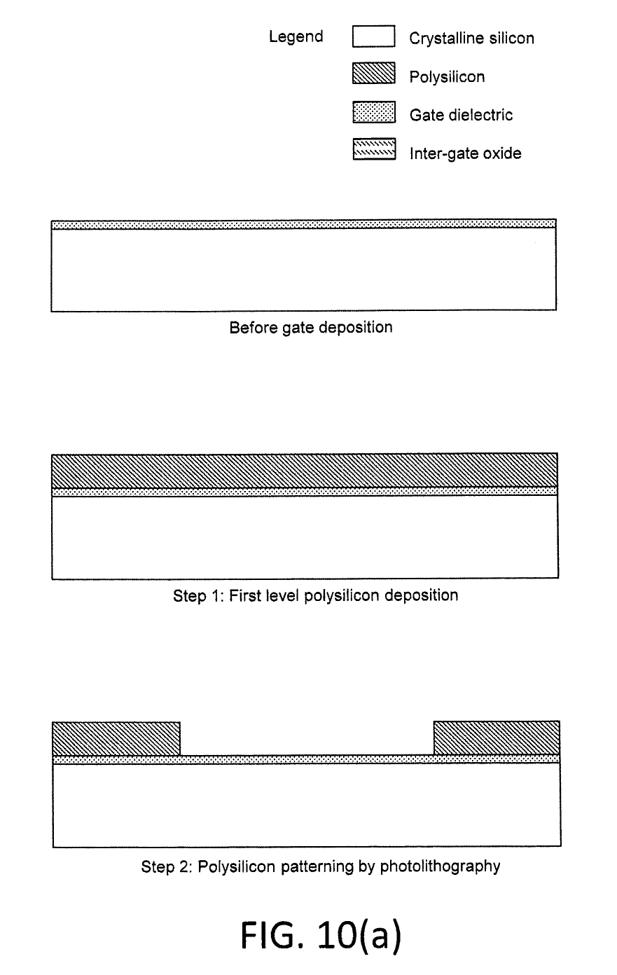

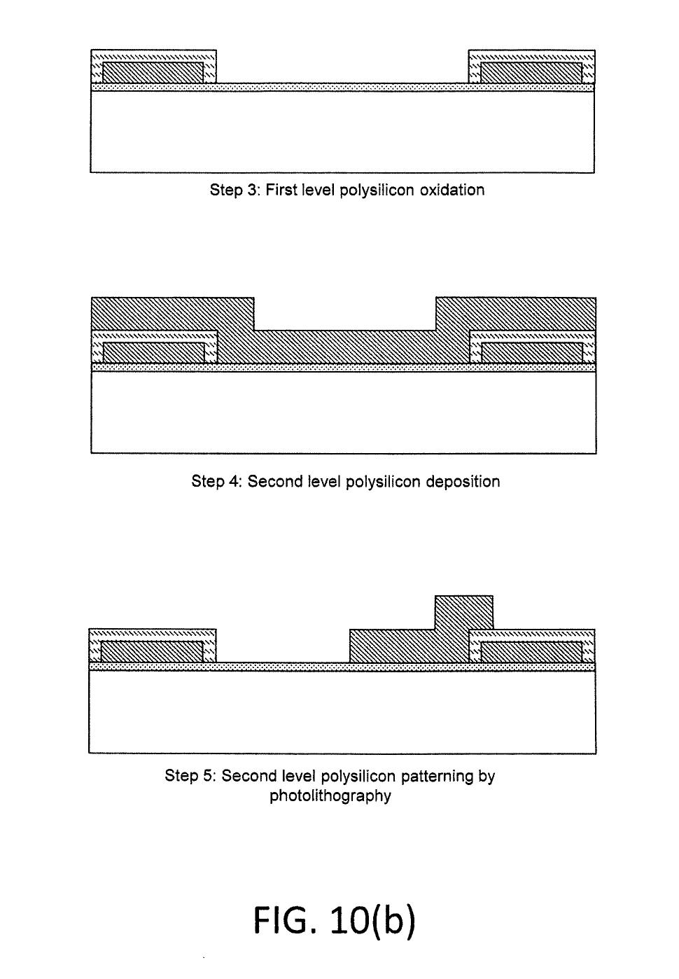

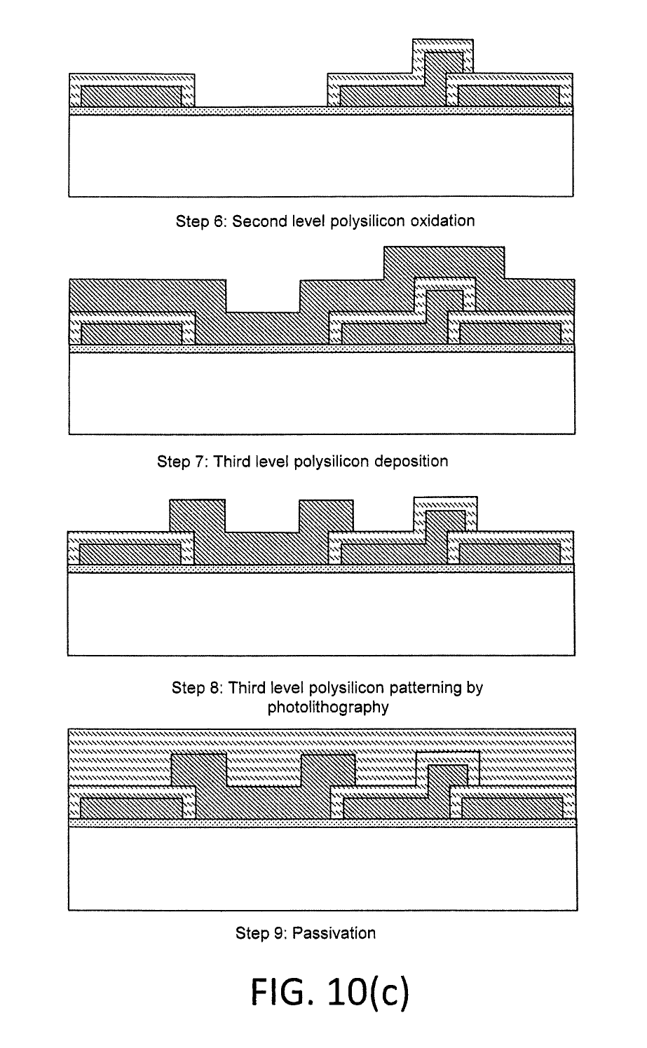

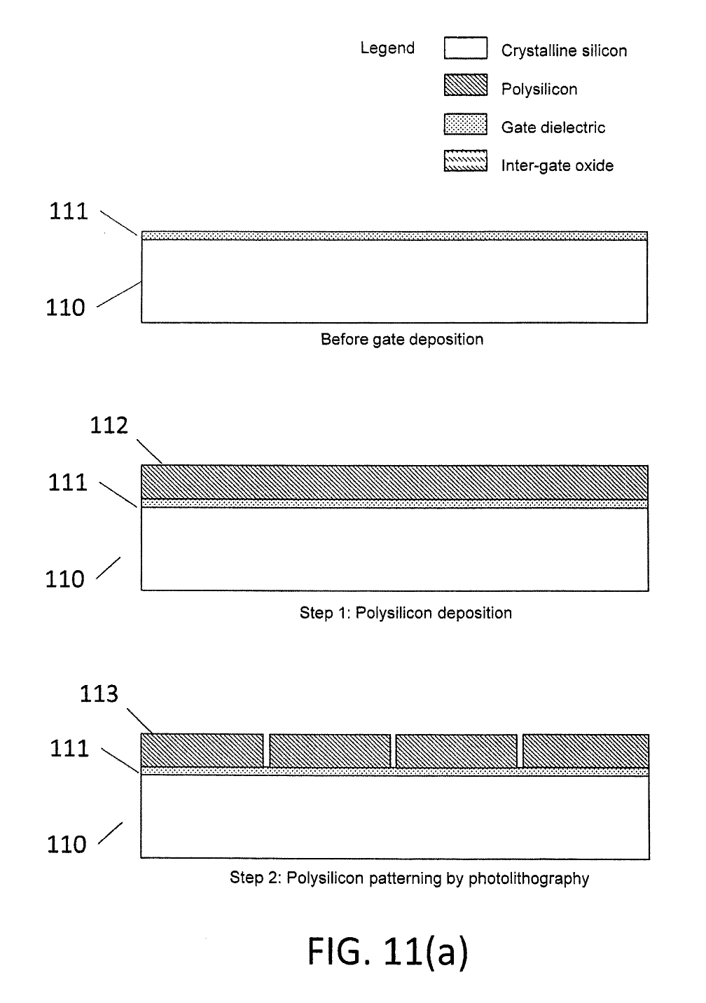

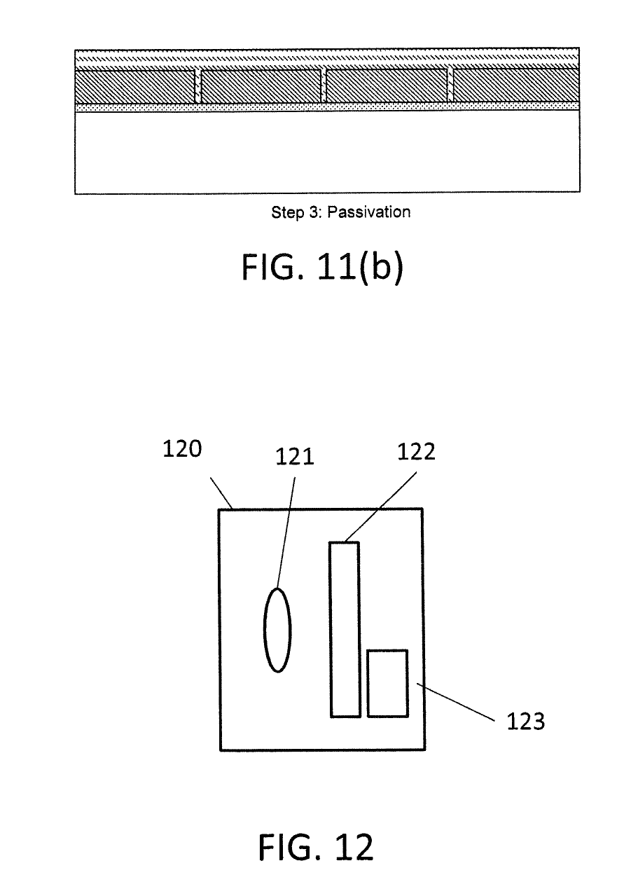

FIGS. 10 and 11 show the steps in manufacturing a traditional CCD and a CMOS device, respectively. An explanation of these will assist in understanding the nature of a CCD embodying the invention but manufactured according to a CMOS process.

FIG. 10a shows the steps of a known CCD manufacturing process showing a silicon layer with gate dielectric deposited thereon. In step 1 a first level of polysilicon deposition is undertaken and in step 2 a required pattern is etched by photolithography. FIG. 10b shows an oxidation step at step 3 followed by a second polysilicon deposition step at step 4. Step 5 shows patterning of the second level polysilicon by photolithography. FIG. 10c shows the remaining steps of the process. Step 6 shows a second level polysilicon oxidation. Step 7 shows a third layer of polysilicon deposition and step 8 patterning of the third level by photolithography. Further layers of polysilicon may be used. Finally step 9 shows passivation of the device.

As can be seen from the steps shown in FIG. 10, four partially overlapping gate electrodes are formed by the combination of deposition and photolithography. The gates are all formed on a dielectric layer separating the gates from the underlying crystalline silicon.

FIGS. 11a and 11b show the steps in a CMOS manufacturing process as used to manufacture an image sensor embodying the invention. Initially crystalline silicon 110 with gate dielectric 111 thereon is provided. In step 1, polysilicon 112 is deposited on the gate dielectric. The process then differs from the previous CCD process at step 2 in that the gate electrodes 113 are formed by photolithography of the polysilicon layer 112 without the need for multiple deposition steps. Lastly, at step 3 a passivation process is undertaken. As can be seen, the process does not use multiple deposition steps, but a single deposition step for the electrode layer of polysilicon.

As discussed above, the embodiment is a CCD image sensor because charge is shifted from one element to another element to achieve transfer from an image area and subsequent multiplication prior to conversion to a signal. However, the techniques for creating the device are typically used to manufacture CMOS devices of the type having signal charge to voltage conversion within each image element.

An apparatus such as a camera or scientific apparatus embodying the invention is shown schematically in FIG. 12. A housing 120 contains a lens arrangement 121 which focuses received illumination onto an image sensor 122 of the type described in relation to the embodiment. Circuitry 123 is provided to receive signals from the image sensor 123 for subsequent processing.

1. A CCD image sensor of the type for providing charge multiplication by impact ionisation, comprising an image area having a plurality of pixels and a separate multiplication register having a plurality of multiplication elements arranged to receive charge from the pixels of the image area, each multiplication element comprising a sequence of electrodes operable to cause charge multiplication, wherein the electrodes of each multiplication element are adjacent one another and non-overlapping.

2. The CCD image sensor according to claim 1, wherein the electrodes are derived from a single layer.

3. The CCD image sensor according to claim 1, wherein the electrodes are formed by etching.

4. The CCD image sensor according to claim 1, wherein the electrodes and manufactured using a CMOS process.

5. The CCD images sensor according to claim 1, wherein the electrodes are derived from a single layer of polysilicon.

6. The CCD image sensor according to claim 1, wherein each multiplication element comprises a sequence of electrodes on a gate dielectric, wherein the gate dielectric is thinner than 20 nm.

7. The CCD image sensor according to claim 1, wherein the electrodes of each multiplication element have inter-electrode gaps that are narrower than 100 nm.

8. The CCD image sensor according to claim 1, wherein the pixels of the image area are arranged in rows and columns and comprising a single multiplication register arranged to receive charge from the pixels of the image area.

9. The CCD image sensor according to claim 1, wherein the pixels of the image area are arranged in rows and columns and comprising a plurality of multiplication registers, each multiplication register arranged to receive charge from a subset of the pixels of the image area.

10. The CCD image sensor according to claim 9, wherein each multiplication register is arranged to receive charge from a corresponding column of the image area.

11. The CCD image sensor according to claim 9, comprising charge to signal converters arranged to produce a signal from each multiplication register and an output multiplexer arranged to receive the signals and implemented to reduce the number of output connections.

12. The CCD image sensor according to claim 1, wherein the electrodes are on a front face of a substrate and the CCD image sensor is arranged for illumination on the back face thereof.

13. An apparatus comprising a CCD image sensor according to claim 1.

14. (canceled)

15. A camera comprising the CCD image sensor according to claim 1.
